(19) United States
(12) Patent Application Publication
(10) Pub. No.: US 2011/0089569 A1
(43) Pub. Date: Apr. 21, 2011

(54) Multilayer wiring, method for placing dummy wiring in multilayer wiring, semiconductor device, and semiconductor device manufacturing method

(75) Inventor: Kazuhiko Asakawa, Tokyo (JP)

(73) Assignee: OKI SEMICONDUCTOR CO., LTD., Tokyo (JP)

(21) Appl. No.: 12/801,551

(22) Filed: Jun. 14, 2010

(30) Foreign Application Priority Data
Jun. 16, 2009 (JP) 2009-143522

(51) Int. Cl. H01L 23/52; H01L 21/768

(52) U.S. Cl. 257/773; 438/622; 257/E21.575; 257/E23.141

(57) ABSTRACT

A multilayer wiring in which plural metal wirings and plural interlayer insulating films are layered, each interlayer insulating film being planarized each time formed, is divided into plural regions. The percentage of an area occupied by each of the metal wirings within each region is obtained for each of the metal wirings. An integral percentage is obtained per region by integrating, the percentages. The integral percentages are used to calculate the relative positional relationship of upper surfaces of the interlayer insulating films of plural regions, from the relative values of the integral percentages obtained beforehand and relative positions of the upper surfaces. In regions where the upper surface is of a height lower than a predetermined value, a dummy wiring is disposed, and in regions where the upper surface is of a height equal to or greater than the predetermined value, a dummy wiring is not disposed.

### CROSS-REFERENCE TO RELATED APPLICATION

This application claims priority under 35 USC 119 from Japanese Patent Application No. 2009-143522, filed on Jun. 16, 2009, the disclosure of which is incorporated by reference herein.

### BACKGROUND OF THE INVENTION

1. Field of the Invention

The present invention relates to multilayer wiring, a method for placing dummy wiring in multilayer wiring, a semiconductor device, and a semiconductor device manufacturing method. The present invention particularly relates to a multilayer wiring formed in a semiconductor substrate, a method for placing dummy wirings in the multilayer wiring, a semiconductor device equipped with the multilayer wiring, and a method of manufacturing the semiconductor device.

2. Description of the Related Art

In recent years, as the miniaturization of semiconductor devices has progressed, the planarization of microfabricated surfaces has been demanded. In manufacturing a semiconductor device equipped with a multilayer wiring, where plural layers of metal wirings and plural layers of interlayer insulating films are layered, chemical mechanical polishing (CMP) is used to planarize the interlayer insulating films, each time each layer of the interlayer insulating films is formed. During planarization by CMP, depending on the wiring density of the metal wiring, thickness variations (so-called global thickness variations) end up arising in the interlayer insulating film that covers the metal wiring. Accordingly, in order to reduce global thickness variations, a metal dummy wiring is placed in a metal wiring regions where the wiring density is small, to thereby raise the wiring density. Such dummy wiring placement can reduce global thickness variations. Further, conventionally, the dummy wiring placement regions have been decided per metal wiring layer.

Taking an LSI circuit such as a logic circuit as an example, in a multilayer wiring of a semiconductor device, the metal wirings are configured by two to seven layers. When the metal wiring layers are plural layers, the interlayer insulating films also become plural layers in accordance therewith. When the metal wiring layers and the interlayer insulating films are plural layers, global thickness variations, at the stage when planarization by CMP of the last interlayer insulating film directly under the uppermost layer of the metal wiring is completed, are decided by relative differences in values obtained by integrating the wiring densities of each of the metal wiring layers in regard to the plural layers of the metal wirings. However, conventional methods do not decide the dummy wiring placement regions, such that the effect of reducing global thickness variations becomes optimum, at the stage when planarization of the last interlayer insulating film is completed. Thus, in conventional methods, when the positions of rough and fine regions in the wiring density distribution before dummy wiring placement differ per metal wiring layer, the effect of inserting dummy wirings has been insufficient.

### SUMMARY OF THE INVENTION

The present invention provides a multilayer wiring that can reduce global thickness variations in an interlayer insulating film directly under an uppermost layer of a metal wiring, a method for placing dummy wiring in multilayer wiring, a semiconductor device, and a semiconductor device manufacturing method.

A first aspect of the invention is a method for placing dummy wirings in a multilayer wiring which includes a plurality of layers of metal wirings and a plurality of layers of interlayer insulating films, alternately layered one layer at a time, each interlayer insulating film being polished and planarized each time each interlayer insulating film is formed, the method comprising: dividing the multilayer wiring into a plurality of regions in a plane intersecting a layering direction of the plurality of layers of the metal wirings and the interlayer insulating films; obtaining, for each layer of the metal wirings excluding an uppermost layer of the metal wirings, per region, the percentage of the area occupied by the metal wirings inside the region with respect to the area of the region; obtaining, per region, an integral percentage by integrating the percentages of the plurality of layers of the metal wirings, excluding the uppermost layer of the metal wirings; using the integral percentages to obtain, from the relationship between relative values of the integral percentages of the metal wirings of the plurality of regions obtained beforehand, and relative positions, in the layering direction, of the upper surfaces of the interlayer insulating film located directly under the uppermost layer of the metal wirings, the relative positional relationship, in the layering direction, of upper surfaces of the interlayer insulating films in the plurality of regions; and with respect to the regions where the interlayer insulating film upper surface is highest, not disposing a dummy wiring in layers of the metal wirings in the regions where the interlayer insulating film upper surface is of a height equal to or greater than a predetermined value, and disposing a dummy wiring in layers where there is at least one layer of the metal wirings of the plurality of layers of metal wirings in the regions where the interlayer insulating film upper surface is of a height lower than the predetermined value.

A second aspect of the invention is a method for manufacturing a semiconductor device including a multilayer wiring which includes a plurality of layers of metal wirings and a plurality of layers of interlayer insulating films, alternately layered one layer at a time on a semiconductor substrate, each interlayer insulating film being polished and planarized each time each interlayer insulating film is formed, the method comprising the step of forming the multilayer wiring by: dividing the multilayer wiring into a plurality of regions in a plane intersecting a layering direction of the plurality of layers of the metal wirings and the plurality of layers of the interlayer insulating films; obtaining, for each layer of the metal wirings excluding an uppermost layer of the metal wirings, per region, the percentage of the area occupied by the metal wirings inside the region with respect to the area of the region; obtaining, per region, an integral percentage by integrating the percentages of the plurality of layers of the metal wirings, excluding the uppermost layer of the metal wirings; using the integral percentages to obtain, from the relationship between relative values of the integral percentages of the metal wirings of the plurality of regions obtained beforehand, and relative positions, in the layering direction, of the upper surfaces of the interlayer insulating film located directly under the uppermost layer of the metal wirings, the relative positional relationship, in the layering direction, of upper surfaces of the interlayer insulating film in the plurality of regions; and with respect to the regions where the interlayer insulating film upper surface is highest, not disposing a dummy wiring in layers of the metal wirings in the regions where the interlayer insulating film upper surface is of a height equal to or greater than a predetermined value, and disposing a dummy wiring in layers where there is at least one layer of the metal wirings of the plurality of layers of metal wirings in the regions where the interlayer insulating film upper surface is of a height lower than the predetermined value.

A third aspect of the invention is a multilayer wiring including a plurality of layers of metal wirings and a plurality of layers of interlayer insulating films, alternately layered one layer at a time, each interlayer insulating film being polished and planarized each time each interlayer insulating film is formed, the multilayer wiring being formed by: dividing the multilayer wiring into a plurality of regions in a plane intersecting a layering direction of the plurality of layers of the metal wirings and the plurality of layers of the interlayer insulating films; obtaining, for each layer of the metal wirings excluding an uppermost layer of the metal wirings, per region, the percentage of the area occupied by the metal wirings inside the region with respect to the area of the region; obtaining, per region, an integral percentage by integrating the percentages of the plurality of layers of the metal wirings, excluding the uppermost layer of the metal wirings; using the integral percentages to obtain, from the relationship between relative values of the integral percentages of the metal wirings of the plurality of regions obtained beforehand, and relative positions, in the layering direction, of the upper surfaces of the interlayer insulating film located directly under the uppermost layer of the metal wirings, the relative positional relationship, in the layering direction, of upper surfaces of the interlayer insulating film in the plurality of regions; and with respect to the regions where the interlayer insulating film upper surface is highest, not disposing a dummy wiring in layers of the metal wirings in the regions where the interlayer insulating film upper surface is of a height equal to or greater than a predetermined value, and disposing a dummy wiring in layers where there is at least one layer of the metal wirings of the plurality of layers of metal wirings in the regions where the interlayer insulating film upper surface is of a height lower than the predetermined value.

A fourth aspect of the invention is a semiconductor device including a multilayer wiring including a plurality of layers of metal wirings and a plurality of layers of interlayer insulating films, alternately layered one layer at a time on a semiconductor substrate, each interlayer insulating film being polished and planarized each time each interlayer insulating film is formed, the multilayer wiring being formed by: dividing the multilayer wiring into a plurality of regions in a plane intersecting a layering direction of the plurality of layers of the metal wirings and the plurality of layers of the interlayer insulating films; obtaining, for each layer of the metal wirings excluding an uppermost layer of the metal wirings, per region, the percentage of the area occupied by the metal wirings inside the region with respect to the area of the region; obtaining, per region, an integral percentage by integrating the percentages of the plurality of layers of the metal wirings excluding the uppermost layer of the metal wirings; using the integral percentages to obtain from the relationship between relative values of the integral percentages of the metal wirings of the plurality of regions obtained beforehand, and relative positions, in the layering direction, of the upper surfaces of the interlayer insulating film located directly under the uppermost layer of the metal wirings, the relative positional relationship, in the layering direction, of upper surfaces of the interlayer insulating film in the plurality of regions; and with respect to the regions where the interlayer insulating film upper surface is highest, not disposing a dummy wiring in layers of the metal wirings in the regions where the interlayer insulating film upper surface is of a height equal to or greater than a predetermined value, and disposing a dummy wiring in layers where there is at least one layer of the metal wirings of the plurality of layers of metal wirings in the regions where the interlayer insulating film upper surface is of a height lower than the predetermined value.

A fifth aspect of the invention, in the above described aspects, wherein in the regions where the interlayer insulating film upper surface is of a height equal to or greater than the predetermined value, when the percentage of the area occupied by an upper layer of the metal wirings is smaller than the percentage of the area occupied by two underlying layers of the metal wirings, the dummy wiring is not disposed in the layers of the two underlying layers of the metal wirings or in the layer of the upper layer of the metal wirings.

According to the aspects described above, the present invention can provide a multilayer wiring that can reduce global thickness variations in an interlayer insulating film directly under an uppermost layer of metal wiring, a method for placing dummy wiring in multilayer wiring, a semiconductor device, and a semiconductor device manufacturing method.

### BRIEF DESCRIPTION OF THE DRAWINGS

Exemplary embodiment of the present invention will be described in detail based on the following figures, wherein:

FIG. 1 is a general longitudinal sectional view for describing a method of planarizing an interlayer insulating film of a multilayer wiring;

FIG. 2 is a general longitudinal sectional view for describing a method of planarizing an interlayer insulating film of a multilayer wiring;

FIG. 3 is a general longitudinal sectional view for describing a method of planarizing an interlayer insulating film of a multilayer wiring;

FIG. 4 is a general plan view for describing a method of dividing a multilayer wiring of the exemplary embodiment into plural regions;

FIG. 5A to FIG. 5C are general plan views for describing the multilayer wiring of the exemplary embodiment;

FIG. 6 is a general longitudinal sectional view for describing the multilayer wiring of the exemplary embodiment; and

FIG. 7 is a general longitudinal sectional view for describing a multilayer wiring for comparison.

### DETAILED DESCRIPTION OF THE INVENTION

Exemplary embodiment of the present invention will be described below with reference to the drawings.

First, the relationship between the wiring density of a metal wiring, and global thickness variations that arise when an interlayer insulating film is planarized by CMP, will be described.

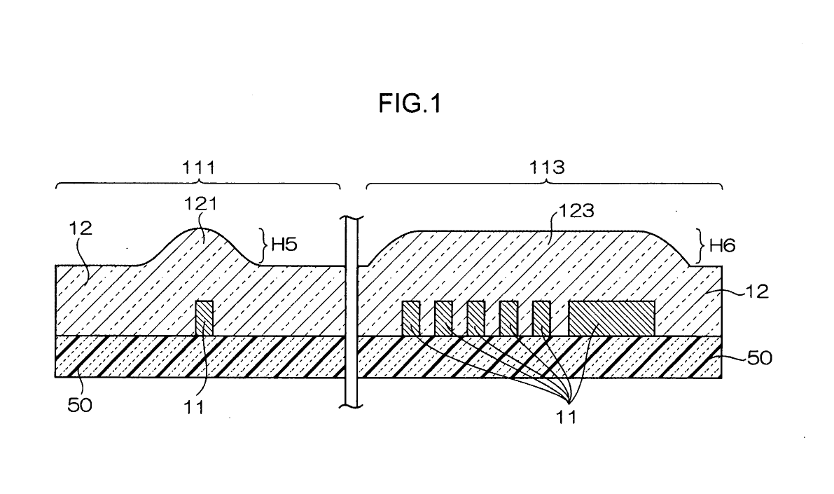

As shown in FIG. 1, a first layer of a metal wiring 11 is formed on a semiconductor substrate 50. Next, a first layer of an interlayer insulating film 12 is formed to cover the metal wiring 11. The interlayer insulating film 12 is formed by plasma chemical vapor deposition (CVD) or atmospheric vapor deposition (VD). At this time, in a high density region 113 where the wiring density of the underlying metal wiring 11 is dense, a raised portion 123 arises on the surface of the interlayer insulating film 12, such that a surface thickness variation H6 arises. On the other hand, in a low density region 111 where the wiring density of the underlying metal wiring 11 is sparse, a raised portion 121 arises on the surface of the interlayer insulating film 12 such that a surface thickness variation H5 arises.

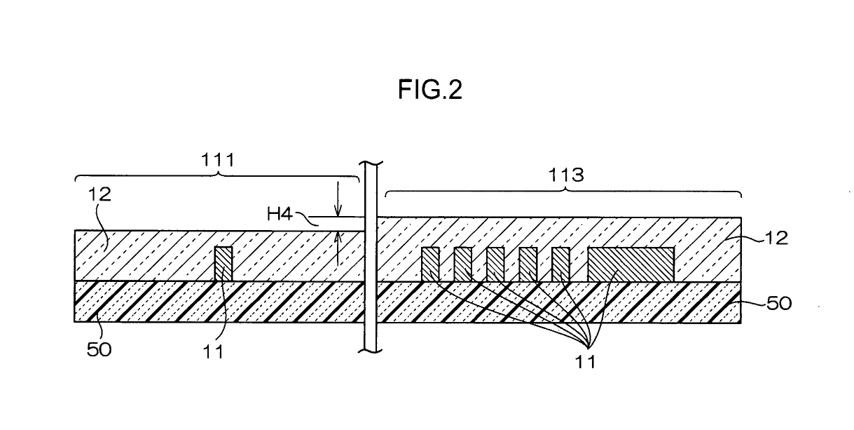

Next, as shown in FIG. 2, the surface of the interlayer insulating film 12 is polished by CMP. Thus, the raised portion 121 and the raised portion 123 disappear such that the surface thickness variations H5 and H6 also disappear. Due thereto, the surface of the interlayer insulating film 12 is respectively planarized in the low density region 111 and in the high density region 113.

However, the film thickness of the interlayer insulating film 12 after CMP is strongly dependent on the wiring density of the underlying metal wiring 11. The larger the wiring density is, the thicker the film thickness after CMP becomes. This is because the shape of the surface of the interlayer insulating film 12 changes, depending on the wiring density of the underlying metal wiring 11. The raised portion 121 that is formed on the surface of the interlayer insulating film 12 on the metal wiring 11 in the low density region 111 has a steeper shape than the raised portion 123 in the high density region 113. Further, the steeper the raised portions 121 and 123 are, the easier it becomes for concentration of pressure from the CMP polishing pad to occur. Accordingly, the steeper the raised portions 121 and 123 are, the larger the polishing rate at those portions becomes.

When polishing by CMP is completed, the surface thickness variations H5 and H6 disappear, but the polishing rate fluctuates dependent on the wiring density of the metal wiring 11. For this reason, the film thickness of the interlayer insulating film 12 differs between the low density region 111 and the high density region 113. Consequently, a global thickness variation H4 arises between the low density region 111 and the high density region 113.

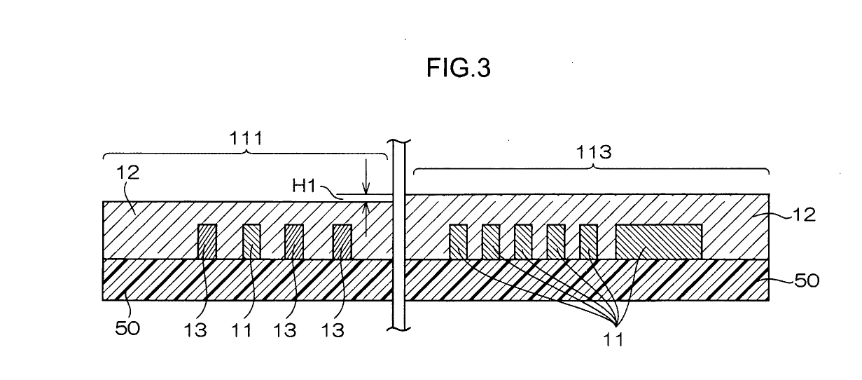

As shown in FIG. 3, as a method of reducing global thickness variations, there is a method that inserts a dummy wiring 13 inside the same layer as the metal wiring 11 in the low density region 111. By adding the dummy wiring 13 in the low density region 111 where the wiring density of the underlying metal wiring 11 is sparse, the wiring density can be raised. As a result, a global thickness variation H1 that arises between the low density region 111 and the high density region 113 can be made small.

Next, the present exemplary embodiment will be described taking as an example a case where semiconductor devices formed on plural chips are manufactured from a single semiconductor substrate (e.g., a single semiconductor wafer).

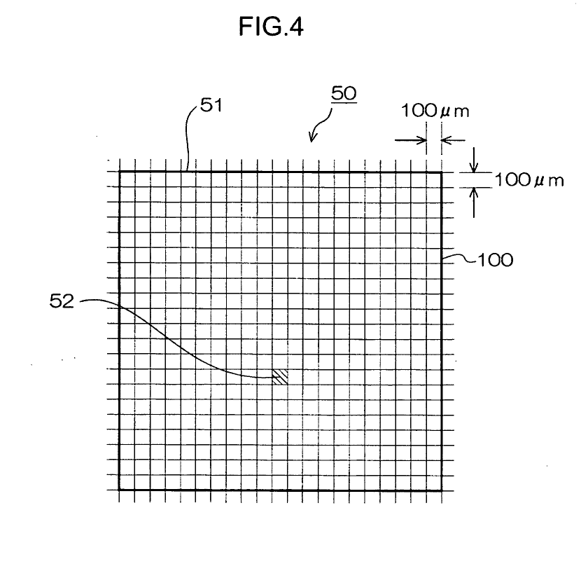

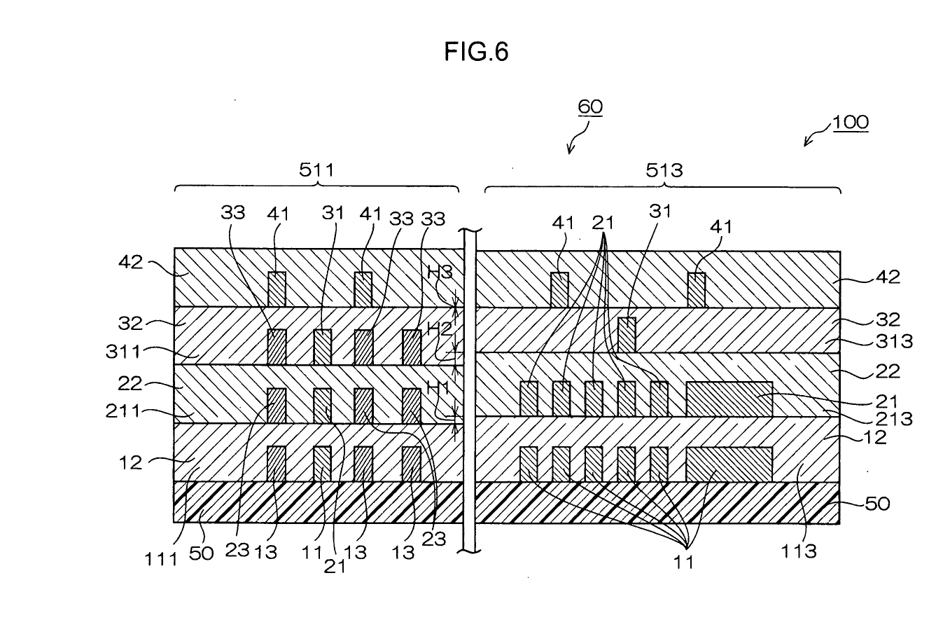

As shown in FIG. 4, plural chips 51 are manufactured from a single semiconductor substrate 50. Elements such as MOSFETs and bipolar transistors (not shown) are formed on each of the chips 51. As shown in FIG. 6, a multilayer wiring 60 is formed on the semiconductor substrate 50. The multilayer wiring 60 is equipped with a first layer of a metal wiring 11, a first layer of a dummy wiring 13, a first layer of an interlayer insulating film 12, a second layer of a metal wiring 21, a second layer of a dummy wiring 23, a second layer of an interlayer insulating film 22, a third layer of a metal wiring 31, a third layer of a dummy wiring 33, a third layer of an interlayer insulating film 32, an uppermost layer of a metal wiring 41, and an insulating film 42. The first layer of the interlayer insulating film 12 is formed to cover the metal wiring 11 and the dummy wiring 13. The second layer of the metal wiring 21 and the second layer of the dummy wiring 23 are formed on the first layer of the interlayer insulating film 12. The second layer of the interlayer insulating film 22 is formed to cover the metal wiring 21 and the dummy wiring 23. The third layer of the metal wiring 31 and the third layer of the dummy wiring 33 are formed on the second layer of the interlayer insulating film 22. The interlayer insulating film 32 of the third layer is formed to cover the metal wiring 31 and the dummy wiring 33. The uppermost layer of the metal wiring 41 is formed on the third layer of the interlayer insulating film 32. Moreover, the insulating film 42 is formed to cover the metal wiring 41. The interlayer insulating films 12, 22 and 32 are polished and planarized by CMP, each time each layer of the interlayer insulating films 12, 22 and 32 is formed.

Next, a method of placing the dummy wirings 13, 23 and 33 will be described.

As shown in FIG. 4, the entire chip 51 is reticulately divided into plural regions 52. Each of the regions 52 is a 100 μm×100 μm square, for example.

First, the percentage of the area occupied by each of the metal wirings 11, 21 and 31 inside the region 52 with respect to the area of the region 52 is obtained in regard to each of the metal wirings 11, 21 and 31 per region 52. The percentage of the area occupied by the uppermost layer of the metal wiring 41 is not obtained.

Next, the percentages of the occupied areas that have been respectively obtained in regard to each of the metal wirings 11, 21 and 31 are integrated per region 52 to obtain an integral percentage.

Next, the relative positional relationship of upper surfaces of the interlayer insulating film 32 of each of the regions 52 is obtained from the relationship between, relative values of the integral percentages of the metal wirings of the regions 52 obtained beforehand, and relative positions of the upper surfaces of the interlayer insulating film 32 directly under the uppermost layer of the metal wiring 41.

Next, regions 52 where the upper surface of the interlayer insulating film 32 is located in a position lower than a predetermined value are calculated, with respect to the region 52 where the upper surface of the interlayer insulating film 32 is located in a highest position. Next, a dummy wiring is disposed for one or more metal wirings of the metal wirings 11, 21 and 31 in the regions 52 that have been calculated. In disposing the dummy wiring, the questions of for which metal wirings of the metal wirings 11, 21 and 31 the dummy wiring will be disposed, for how many metal wirings the dummy wiring will be disposed, and what the wiring density of the dummy wiring will be, are decided such that, the upper surfaces of the interlayer insulating film 32 are in a position equal to or greater than the predetermined value with respect to the region 52 where the upper surface of the interlayer insulating film 32 is located in the lowest position. These matters are decided in consideration of the affect that placement of dummy wiring has on the characteristics of the semiconductor device.

On the other hand, a dummy wiring is not disposed in regard to layers of the plural layers of the metal wirings 11, 21 and 31 in the region where the upper surface of the interlayer insulating film 32 is of a height equal to or greater than the predetermined value (with respect to the region where the upper surface of the interlayer insulating film 32 is located in the highest position).

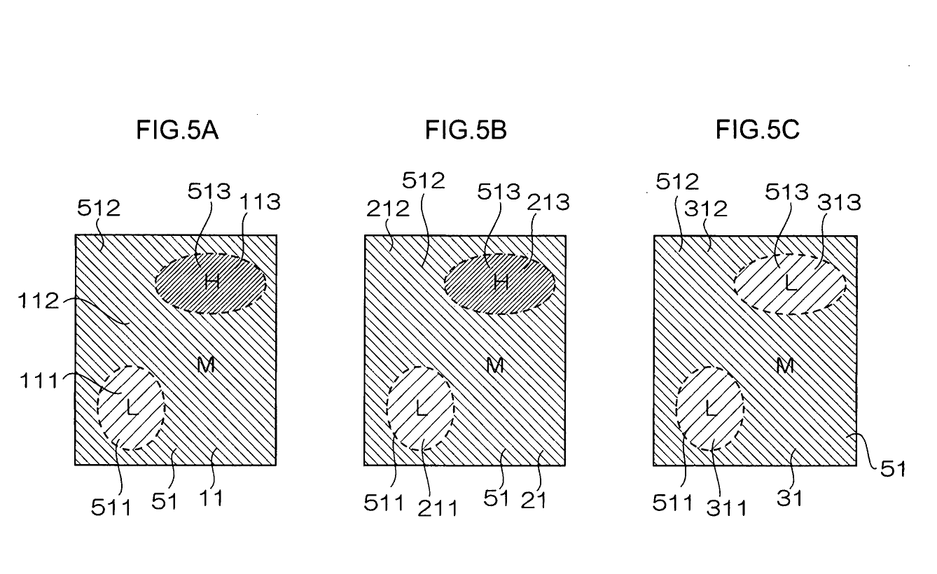

FIG. 5A to FIG. 5C show distributions of the wiring densities of the regions 52, before dummy wiring placement that have been obtained as described above.

As shown in FIG. 5A, the first layer of the metal wiring 11 has low density regions 111 where the wiring density is low, moderate density regions 112 where the wiring density is moderate, and high density regions 113 where the wiring density is high.

As shown in FIG. 5B, the second layer of the metal wiring 21 has low density regions 211, moderate density regions 212, and high density regions 213.

As shown in FIG. 5C, the third layer of the metal wiring 31 has low density regions 311, moderate density regions 312, and low density regions 313.

The low density regions 211 of the second layer exist on the low density regions 111 of the first layer. Further, the low density regions 311 of the third layer exist on the low density regions 211 of the second layer. Accordingly, the sum density, that is the sum of the wiring densities of the low density regions 111, the low density regions 211 and the low density regions 311, in these regions, is low. The regions where these regions 111, 211 and 311 exist are low sum density regions 511 where the sum density is low.

The moderate density regions 212 of the second layer exist on the moderate density regions 112 of the first layer. Further, the moderate density regions 312 of the third layer exist on the moderate density regions 212 of the second layer. Accordingly, the sum density that is the sum of the wiring densities of the moderate density regions 112, the moderate density regions 212 and the moderate density regions 312, in these regions, is moderate. The regions where these regions 112, 212 and 312 exist are moderate sum density regions 512 where the sum density is moderate.

The high density regions 213 of the second layer exist on the high density regions 113 of the first layer. Further, the low density regions 313 of the third layer exist on the high density regions 213 of the second layer. Accordingly, the sum density, that is the sum of the wiring densities of the high density regions 113, the high density regions 213 and the low density regions 313, in these regions, is high. The regions where these regions 113, 213 and 313 exist are high sum density regions 513 where the sum density is high.

Next, the relative positional relationship of the upper surfaces of the interlayer insulating film 32 of each of the regions 52, is obtained from the relationship between, relative values of the integral percentages of the metal wirings of the regions 52 obtained beforehand, and relative positions of the upper surfaces of the interlayer insulating film 32 directly under the uppermost layer of the metal wiring 41.

As a result, the regions where the positions of the upper surfaces of the interlayer insulating film 32 are highest, is the high sum density regions 513. Further, the regions where the positions of the upper surfaces of the interlayer insulating film 32 are next highest, is the moderate sum density regions 512. Moreover, the regions where the positions of the upper surfaces of the interlayer insulating film 32 are lowest, is the low sum density regions 511.

When the positions of the upper surfaces of the interlayer insulating film 32 that have been obtained are compared, in the low sum density regions 511, the positions of the upper surfaces of the interlayer insulating film 32, end up being in positions lower than the predetermined value (positions lower than a position determined from global thickness variation tolerance). Further, in the moderate sum density regions 512, the positions of the upper surfaces of the interlayer insulating film 32, end up being in positions higher than the predetermined value (positions higher than a position determined from global thickness variation tolerance).

Thus, in the present exemplary embodiment, a dummy wiring is disposed only in the low sum density regions 511, and a dummy wiring is not disposed in the moderate sum density regions 512 or in the high sum density regions 513.

Next, in consideration of the affect that placement of dummy wiring has on the characteristics of the semiconductor device, the present exemplary embodiment decides the determination of in which metal wiring layers within the low sum density regions 511 the dummy wiring will be disposed, in how many metal wiring layers the dummy wiring will be disposed, and what the wiring density of the dummy wiring will be. In the present exemplary embodiment, dummy wirings are disposed in all of the low density regions 111 of the first layer, the low density regions 211 of the second layer, and the low density regions 311 of the third layer.

In FIG. 6, there is shown a general longitudinal sectional view of the low sum density regions 511 and the high sum density regions 513 of a semiconductor device 100 of the present exemplary embodiment.

In the low sum density regions 511, the dummy wiring 13 is disposed in the low density regions 111 of the first layer, the dummy wiring 23 is disposed in the low density regions 211 of the second layer, and the dummy wiring 33 is disposed in the low density regions 311 of the third layer.

In the high sum density regions 513, a dummy wiring is not disposed in the high density regions 113 of the first layer or in the high density regions 213 of the second layer. Moreover, a dummy wiring is also not disposed in the low density regions 313 of the third layer.

In the present exemplary embodiment, dummy wirings are placed as described above. As a result, in the first layer of the interlayer insulating film 12, a global thickness variation H1 arises. Further, in the second layer of the interlayer insulating film 22, a global thickness variation H2, that is about twice the global thickness variation H1, arises. However, in the third layer of the interlayer insulating film 32, a global thickness variation H3 virtually does not arise.

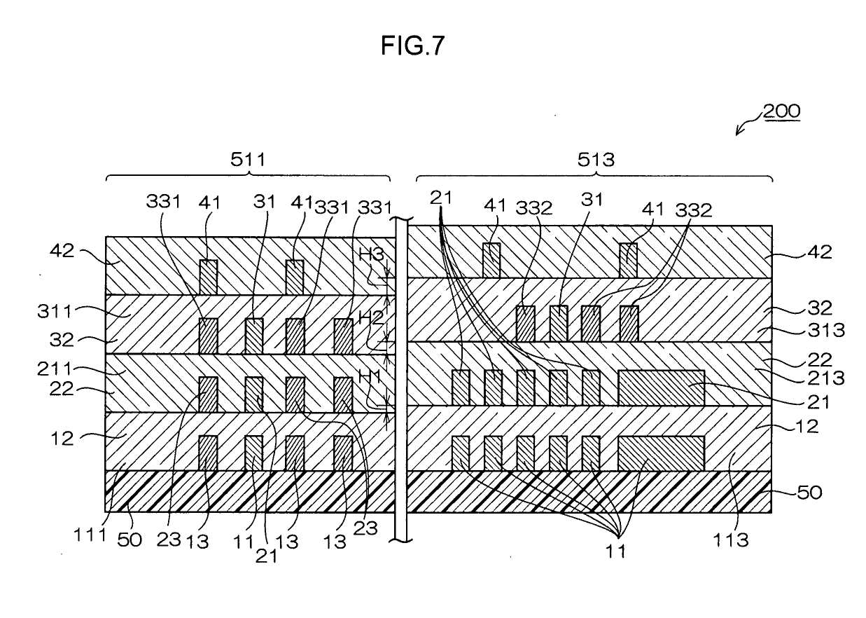

FIG. 7 shows a general longitudinal sectional view of a semiconductor device 200, in a case where only the wiring densities in the respective layers of the metal wirings 11, 21 and 31 are considered, when disposing dummy wirings.

The low density regions 111 of the first layer, the low density regions 211 of the second layer, and the low density regions 311 of the third layer, are all regions where the wiring density is low. Accordingly, in this case, the dummy wiring 13 is disposed in the low density regions 111 of the first layer, the dummy wiring 23 is disposed in the low density regions 211 of the second layer, and a dummy wiring 331 is disposed in the low density regions 311 of the third layer.

Further, a dummy wiring is not disposed in the high density regions 113 of the first layer or in the high density regions 213 of the second layer, because the high density regions 113 of the first layer and the high density regions 213 of the second layer are regions where the wiring density is high. However, a dummy wiring 332 is disposed in the low density regions 313 of the third layer, because the low density regions 313 of the third layer are regions where the wiring density is low.

When dummy wirings are placed in consideration of only the wiring densities as described above, in the first layer of the interlayer insulating film 12, a global variation difference H1 arises. Further, in the second layer of the interlayer insulating film 22, a global thickness variation H2, that is about twice the global thickness variation H1, arises. Moreover, in the third layer of the interlayer insulating film 32, a global thickness variation H3, that is about the same as the global thickness variation H2, ends up arising as a result of disposing the dummy wiring 332.

In the present exemplary embodiment, there are no particular limits in regard to the dimensions of the dummy wirings. The dimensions of the dummy wirings 13, 23 and 33 may be 2 μm×2 μm, for example, and the intervals between the dummy wirings may be 2 μm.

Further, in the exemplary embodiment described above, the chip 51 is divided into the 100 μm×100 μm regions 52. However, the present invention is not limited thereto.

What is claimed is:

1. A method for placing dummy wirings in a multilayer wiring which includes a plurality of layers of metal wirings and a plurality of layers of interlayer insulating films, alternately layered one layer at a time, each interlayer insulating film being polished and planarized each time each interlayer insulating film is formed, the method comprising:
dividing the multilayer wiring into a plurality of regions in a plane intersecting a layering direction of the plurality of layers of the metal wirings and the interlayer insulating films;
obtaining, for each layer of the metal wirings excluding an uppermost layer of the metal wirings, per region, the percentage of the area occupied by the metal wirings inside the region with respect to the area of the region;
obtaining, per region, an integral percentage by integrating the percentages of the plurality of layers of the metal wirings, excluding the uppermost layer of the metal wirings;
using the integral percentages to obtain, from the relationship between relative values of the integral percentages of the metal wirings of the plurality of regions obtained beforehand, and relative positions, in the layering direction, of the upper surfaces of the interlayer insulating film located directly under the uppermost layer of the metal wirings, the relative positional relationship, in the layering direction, of upper surfaces of the interlayer insulating films in the plurality of regions; and
with respect to the regions where the interlayer insulating film upper surface is highest,
not disposing a dummy wiring in layers of the metal wirings in the regions where the interlayer insulating film upper surface is of a height equal to or greater than a predetermined value, and
disposing a dummy wiring in layers where there is at least one layer of the metal wirings of the plurality of layers of metal wirings in the regions where the interlayer insulating film upper surface is of a height lower than the predetermined value.

2. The dummy wiring placement method according to claim 1, wherein in the regions where the interlayer insulating film upper surface is of a height equal to or greater than the predetermined value, when the percentage of the area occupied by an upper layer of the metal wirings is smaller than the percentage of the area occupied by two underlying layers of the metal wirings, the dummy wiring is not disposed in the layers of the two underlying layers of the metal wirings, or in the layer of the upper layer of the metal wirings.

3. A method for manufacturing a semiconductor device including a multilayer wiring which includes a plurality of layers of metal wirings and a plurality of layers of interlayer insulating films, alternately layered one layer at a time on a semiconductor substrate, each interlayer insulating film being polished and planarized each time each interlayer insulating film is formed, the method comprising the step of forming the multilayer wiring by:
dividing the multilayer wiring into a plurality of regions in a plane intersecting a layering direction of the plurality of layers of the metal wirings and the plurality of layers of the interlayer insulating films;
obtaining, for each layer of the metal wirings excluding an uppermost layer of the metal wirings, per region, the percentage of the area occupied by the metal wirings inside the region with respect to the area of the region;
obtaining, per region, an integral percentage by integrating the percentages of the plurality of layers of the metal wirings, excluding the uppermost layer of the metal wirings;
using the integral percentages to obtain, from the relationship between relative values of the integral percentages of the metal wirings of the plurality of regions obtained beforehand, and relative positions, in the layering direction, of the upper surfaces of the interlayer insulating film located directly under the uppermost layer of the metal wirings, the relative positional relationship, in the layering direction, of upper surfaces of the interlayer insulating film in the plurality of regions; and
with respect to the regions where the interlayer insulating film upper surface is highest,
not disposing a dummy wiring in layers of the metal wirings in the regions where the interlayer insulating film upper surface is of a height equal to or greater than a predetermined value, and
disposing a dummy wiring in layers where there is at least one layer of the metal wirings of the plurality of layers of metal wirings in the regions where the interlayer insulating film upper surface is of a height lower than the predetermined value.

4. The semiconductor device manufacturing method according to claim 3, wherein in the regions where the interlayer insulating film upper surface is of a height equal to or greater than the predetermined value, when the percentage of the area occupied by an upper layer of the metal wirings is smaller than the percentage of the area occupied by two underlying layers of the metal wirings, the dummy wiring is not disposed in the layers of the two underlying layers of the metal wirings or in the layer of the upper layer of the metal wirings.

5. A multilayer wiring including a plurality of layers of metal wirings and a plurality of layers of interlayer insulating films, alternately layered one layer at a time, each interlayer insulating film being polished and planarized each time each interlayer insulating film is formed, the multilayer wiring being formed by:
dividing the multilayer wiring into a plurality of regions in a plane intersecting a layering direction of the plurality of layers of the metal wirings and the plurality of layers of the interlayer insulating films;
obtaining, for each layer of the metal wirings excluding an uppermost layer of the metal wirings, per region, the percentage of the area occupied by the metal wirings inside the region with respect to the area of the region;
obtaining, per region, an integral percentage by integrating the percentages of the plurality of layers of the metal wirings, excluding the uppermost layer of the metal wirings;
using the integral percentages to obtain, from the relationship between relative values of the integral percentages of the metal wirings of the plurality of regions obtained beforehand, and relative positions, in the layering direction, of the upper surfaces of the interlayer insulating film located directly under the uppermost layer of the metal wirings, the relative positional relationship, in the layering direction, of upper surfaces of the interlayer insulating film in the plurality of regions; and
with respect to the regions where the interlayer insulating film upper surface is highest,
not disposing a dummy wiring in layers of the metal wirings in the regions where the interlayer insulating film upper surface is of a height equal to or greater than a predetermined value, and
disposing a dummy wiring in layers where there is at least one layer of the metal wirings of the plurality of layers of metal wirings in the regions where the interlayer insulating film upper surface is of a height lower than the predetermined value.

6. The multilayer wiring according to claim 5, wherein in the regions where the interlayer insulating film upper surface is of a height equal to or greater than the predetermined value, when the percentage of the area occupied by an upper layer of the metal wirings is smaller than the percentage of the area occupied by two underlying layers of the metal wirings, the dummy wiring is not disposed in the layers of the two underlying layers of the metal wirings or in the layer of the upper layer of the metal wirings.

7. A semiconductor device including a multilayer wiring including a plurality of layers of metal wirings and a plurality of layers of interlayer insulating films, alternately layered one layer at a time on a semiconductor substrate, each interlayer insulating film being polished and planarized each time each interlayer insulating film is formed, the multilayer wiring being formed by:
dividing the multilayer wiring into a plurality of regions in a plane intersecting a layering direction of the plurality of layers of the metal wirings and the plurality of layers of the interlayer insulating films;
obtaining, for each layer of the metal wirings excluding an uppermost layer of the metal wirings, per region, the percentage of the area occupied by the metal wirings inside the region with respect to the area of the region;
obtaining, per region, an integral percentage by integrating the percentages of the plurality of layers of the metal wirings excluding the uppermost layer of the metal wirings;
using the integral percentages to obtain from the relationship between relative values of the integral percentages of the metal wirings of the plurality of regions obtained beforehand, and relative positions, in the layering direction, of the upper surfaces of the interlayer insulating film located directly under the uppermost layer of the metal wirings, the relative positional relationship, in the layering direction, of upper surfaces of the interlayer insulating film in the plurality of regions; and
with respect to the regions where the interlayer insulating film upper surface is highest,
not disposing a dummy wiring in layers of the metal wirings in the regions where the interlayer insulating film upper surface is of a height equal to or greater than a predetermined value, and
disposing a dummy wiring in layers where there is at least one layer of the metal wirings of the plurality of layers of metal wirings in the regions where the interlayer insulating film upper surface is of a height lower than the predetermined value.

8. The semiconductor device according to claim 7, wherein in the regions where the interlayer insulating film upper surface is of a height equal to or greater than the predetermined value, when the percentage of the area occupied by an upper layer of the metal wirings is smaller than the percentage of the area occupied by two underlying layers of the metal wirings, the dummy wiring is not disposed in the layers of the two underlying layers of the metal wirings or in the layer of the upper layer of the metal wirings.
